(19) United States
(12) Patent Application Publication
(10) Pub. No.: US 2008/0164011 A1
(43) Pub. Date: Jul. 10, 2008

(54) Liquid cooling type heat-dissipating device

(75) Inventor: Wen-Hua Chen, Hsinchu (TW)

Correspondence Address: BIRCH STEWART KOLASCH & BIRCH, PO BOX 747, FALLS CHURCH, VA, 22040-0747, US

(73) Assignee: INVENTEC CORPORATION

(21) Appl. No.: 11/651,007

(22) Filed: Jan. 9, 2007

(51) Int. Cl. H05K 7/20

(52) U.S. Cl. 165/104.33; 165/80.4; 361/699

(57) ABSTRACT

A liquid cooling type heat-dissipating device for exchanging heat with a heat source is provided, which includes a heat-dissipating fan, a pump, a liquid pipe, a motor, and a heat-dissipating block. The motor drives the heat-dissipating fan and the pump. Two ends of the liquid pipe are connected to the pump so as to form a fluid loop, wherein the liquid pipe is in contact with the heat-dissipating block, and the heat-dissipating block is disposed on the heat source. The liquid pipe is continuously curved on a segment away from the heat-dissipating block to form a curved portion located on a wind output path of the heat-dissipating fan, therefore, the heat-dissipating fan cools the curved portion by blowing wind, so as to increase the speed of temperature dropping thereby improving the heat dissipation performance of the liquid pipe.

### BACKGROUND OF THE INVENTION

1. Field of Invention

The present invention relates to a liquid cooling type heat-dissipating device, and more particularly to a heat-dissipating device that can improve the cooling capability of a liquid pipe.

2. Related Art

Electronic elements such as a central processing unit (CPU) and a power integrated circuit (IC) in the computer generate heat when performing operation and a working temperature is also increased as the operation process goes on. Because the working temperature has a significant effect on whether a breakdown occurs to the computer equipment, in order to reduce the working temperature of the electronic elements that generate heat and keep the electronic elements well function, a variety of heat-dissipating devices have been introduced, one of which is, for example, a liquid cooling type heat-dissipating device. The liquid cooling type heat-dissipating device includes a heat sink, a coolant cycling apparatus and a fan. The coolant cycling apparatus has a motor for cycling water or other liquid coolant, and the fan is driven by another motor for blowing. In this manner, the arrangement of two motor increases the number of the components required and the overall assembly volume of the liquid cooling type heat-dissipating device and two sets of power supply are needed to provide power to the motors, thereby increasing power consumption.

Accordingly, in order to reduce the volume and power consumption, a liquid cooling type heat-dissipating device is introduced that has a coolant cycling apparatus and a fan driven by a same motor. Referring to FIG. 1, the liquid cooling type heat-dissipating device includes a motor apparatus 10a, a heat-dissipating fan apparatus 20a and a coolant cycling apparatus 30a. Two ends of the motor apparatus 10a are respectively connected to the heat-dissipating fan apparatus 20a and the coolant cycling apparatus 30a, where the motor apparatus 10a is made to be coaxial with the heat-dissipating fan apparatus 20a and the coolant cycling apparatus 30a, and thus the motor apparatus 10a can drive both the heat-dissipating fan apparatus 20a and the coolant cycling apparatus 30a so as to rotate fan blades of both the heat-dissipating fan apparatus 20a and the coolant cycling apparatus 30a. Also, the coolant cycling apparatus 30a includes a pipe 33a with a liquid entrance section 36a and a liquid exit section 37a. Additionally, the pipe 33a is connected to a heat sink 38a and a heat exchanger 39a, where the heat sink 38a is in contact with a CPU 100a, so as to dissipate heat from the CPU 100a. The heat exchanger 39a is arranged to the liquid entrance section 36a, and thus coolant in the liquid entrance section 36a may take away the heat from the CPU 100a and then cooled by wind from the heat-dissipating fan apparatus 20a when passing through the section of the pipe 33a in the heat exchanger 39a. Meanwhile, the coolant is cooled by the heat exchanger 39a. In this manner, a heat dissipation and temperature dropping may be performed for the coolant by both the heat-dissipating fan apparatus 20a and the heat exchanger 39a when the coolant flows in the liquid entrance section 36a, and the cooled coolant is then driven by the motor apparatus 10a to enter the liquid exit section 37a. Accordingly, the coolant circularly dissipates its heat continually in the liquid input pipe 36a and the liquid output pipe 37a.

Because the coolant is cooled through the heat-dissipating fan apparatus 20a and the heat exchanger 39a when flowing in the liquid entrance section 36a, when a storage space in the liquid entrance section 36a for the coolant is inadequate, i.e., when the heat-dissipating area of the liquid entrance section 36a is reduced, the time for cooling the working liquid will be reduced, thereby reducing the heat dissipation efficiency.

Furthermore, when the above heat-dissipating fan apparatus 20a generates the wind to cool the liquid input pipe 36a, the air flow enters and exits along an axial direction of the heat-dissipating fan apparatus 20a. The motor apparatus 10a is located in the center of the heat-dissipating fan apparatus 20a, and thus the air flow is baffled when being input and output in the axial direction of the heat-dissipating fan apparatus 20a, so that the maximum air volume and wind pressure occur on the outer edges of the fan blades instead of the center shaft of the motor apparatus 10a, thereby increasing a wind resistance and thus significantly reducing the cooling effect when the heat-dissipating fan apparatus 20a acts on the liquid input pipe 36a via the wind.

### SUMMARY OF THE INVENTION

According to the conventional art disclosed above, the heat-dissipating area is reduced due to an inadequate storage space of a pipe, and the cooling effect of the heat-dissipating fan is reduced due to large wind resistance. In view of this, it is an object of the present invention to provide a liquid cooling type heat-dissipating device, which can improve the heat dissipation effect.

A liquid cooling type heat-dissipating device disclosed according to the present invention includes a heat-dissipating fan, a pump, a liquid pipe, a motor and a heat-dissipating block. Two opposite ends of the motor are connected to the heat-dissipating fan and the pump. Two ends of the liquid pipe are communicated with the pump so as to form a liquid loop, wherein the liquid pipe is in contact with the heat-dissipating block which is disposed on a heat source. The liquid pipe is continuously curved on a segment away from the heat-dissipating block to form a curved portion which is corresponding to a wind output position of the heat-dissipating fan and thus is forwardly blown by the heat-dissipating fan.

The liquid cooling type heat-dissipating device disclosed by the present invention has effects that the heat dissipation efficiency of the liquid pipe may be improved by increasing the heat dissipation area of the liquid pipe, and that the heat-dissipating fan draws the wind via an axial direction and blows the wind via a radial direction, thereby effectively reducing a wind resistance to facilitate the entrance and exit of an air flow and directly acting on the liquid pipe through the wind to improve the cooling capability of the liquid pipe.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

FIG. 1 is a schematic view of the operation of a conventional liquid cooling type heat-dissipating device.

FIGS. 2A and 2B are exploded schematic views of a first embodiment of a liquid cooling type heat-dissipating device according to the present invention.

FIG. 3 is a combined schematic view of the first embodiment of the liquid cooling type heat-dissipating device according to the present invention.

FIG. 4 is a sectional view of the first embodiment of the liquid cooling type heat-dissipating device according to the present invention.

FIG. 5 is a schematic view of a forward air blow of the first embodiment of the liquid cooling type heat-dissipating device according to the present invention.

FIG. 6 is a schematic view of a forward air blow of a second embodiment of the liquid cooling type heat-dissipating device according to the present invention.

FIGS. 7A and 7B are exploded schematic views of a third embodiment of the liquid cooling type heat-dissipating device according to the present invention which is equipped with gear sets.

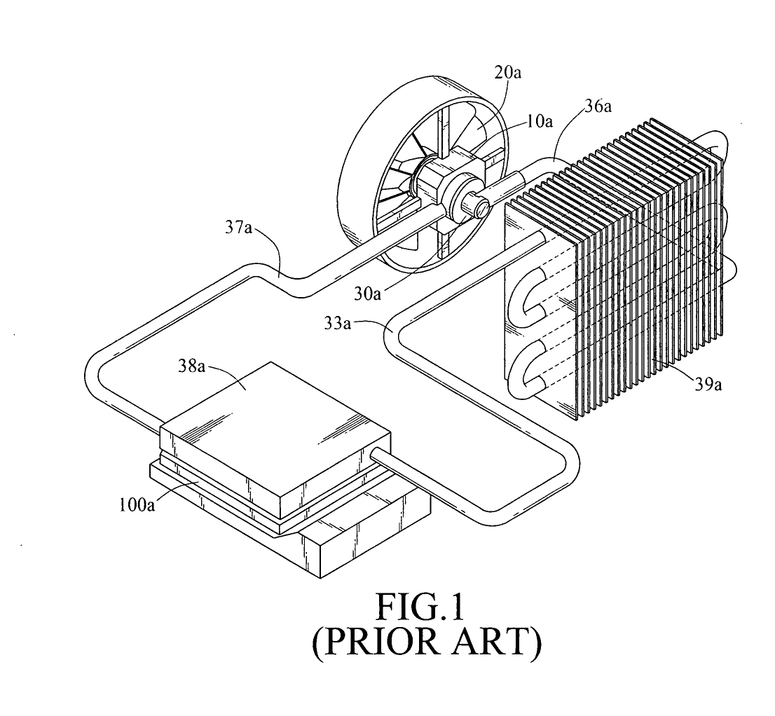

### DETAILED DESCRIPTION OF THE INVENTION

A liquid cooling type heat-dissipating device disclosed according to the present invention is applied to an electronic element that generates heat, where the electronic element is, but not limited to, a CPU or an IC chip. In the following embodiments of the present invention, a CPU will be taken as an illustration in the embodiments of the present invention.

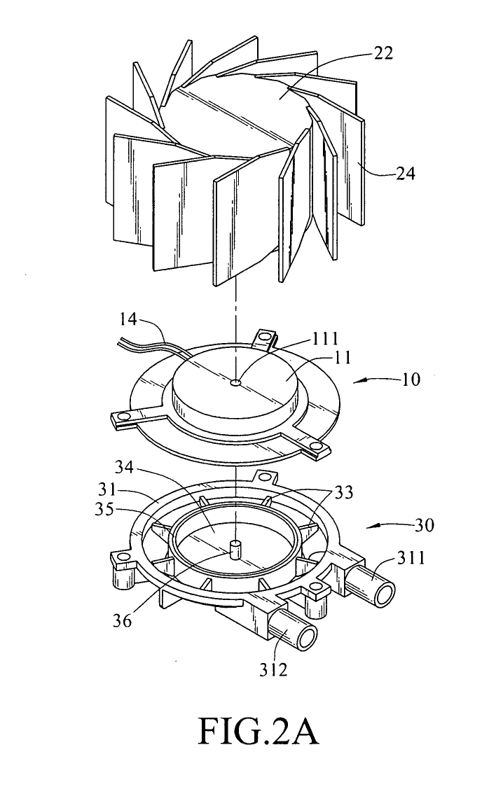

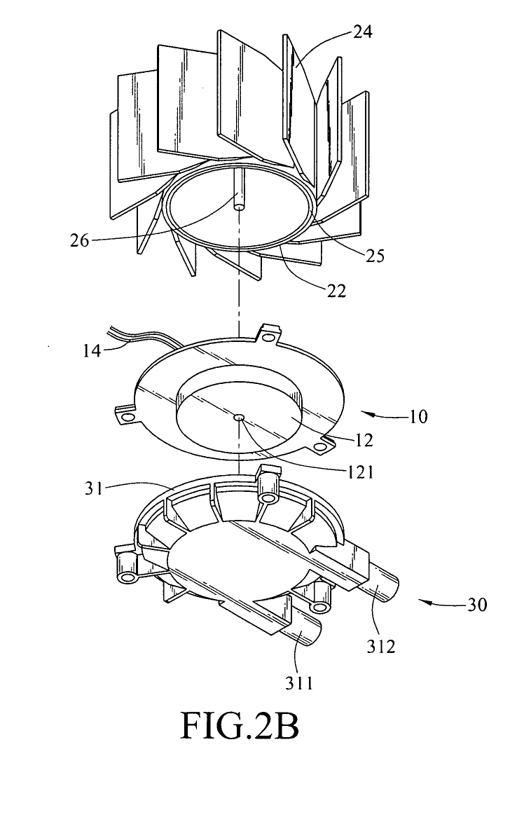

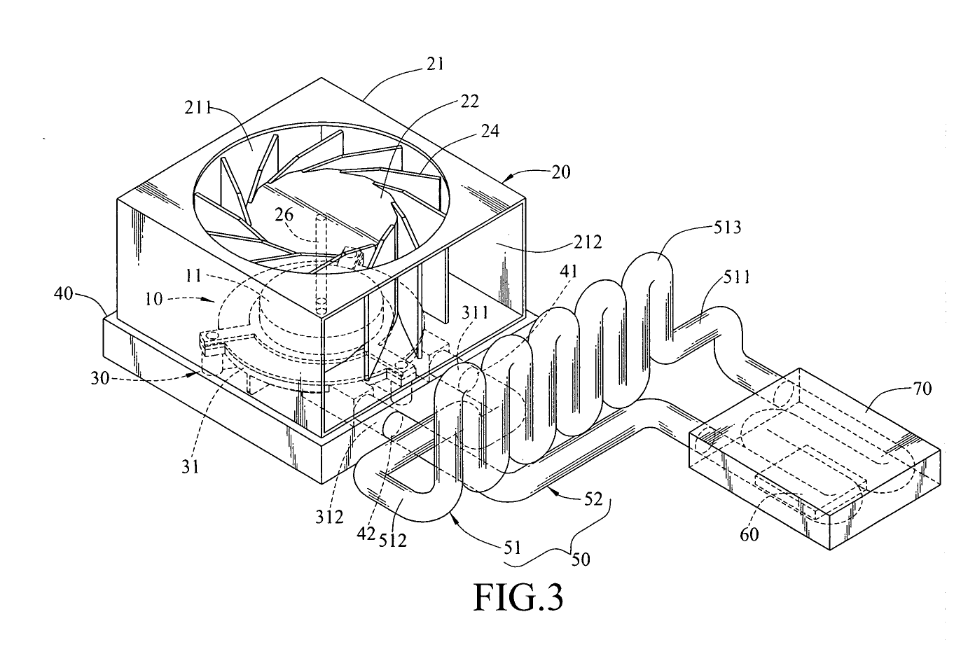

Referring to FIGS. 2A, 2B, and 3, the liquid cooling type heat-dissipating device includes a motor 10, a heat-dissipating fan 20, a pump 30 and a liquid pipe 50. The motor 10 and the pump 30 are located in a casing 40 which is formed with two through holes 41, 42. A first stator 11 and a second stator 12 are respectively projected from two side surfaces of the motor 10, and shaft holes 111, 121 are respectively formed on a end surfaces of the first stator 11 and the second stator 12, such that the two side surfaces of the motor 10 may be connected to the heat-dissipating fan 20 and the pump 30, but the present invention is not limited to shaft holes. Alternatively, shaft pins 26, 36 are respectively disposed on the end surfaces of the first stator 11 and the second stator 12 to achieve the connection. Here, the end surfaces the first stator 11 and the second stator 12 respectively formed with shaft holes 111,121 are taken as an example. Moreover, a power supply wire 14 is provides to electrically connect the motor 10 with an electric power source, so as to provide electric power to the first stator 11 and the second stator 12.

The heat-dissipating fan 20 is located on a top surface of the casing 40, corresponding to the first stator 11, and the heat-dissipating fan 20 includes a frame 21, a fan hub 22 and fan blades 24. The frame 21 encloses the fan hub 22 and the fan blade 24, and the frame 21 is formed with an axial wind inlet 211 and a radial wind outlet 212 for the fan blade 24 to draw or discharge air flow, however, a wind drawing direction and a wind blowing direction thereof are not limited to this. The fan blades 24 are disposed on an outer periphery of the fan hub 22, corresponding to the axial wind inlet 211, a first magnetic element 25 is disposed on the inner wall of the fan hub 22, and the first magnetic element 25 is a magnet. A shaft pin 26 is projected at the axial center of the inner wall of the fan hub 22 corresponding to the position of the shaft hole 111 of the first stator 11, so as to be inserted into the shaft hole 111 of the first stator 11, such that the inner wall of the fan hub 22 may accommodate the stator 11, which helps the first magnetic element 25 and the first stator 11 to induct each other.

The pump 30 is disposed on a bottom surface of the motor 10, and the pump 30 includes a pump housing 31 and a turbine 33. The pump housing 31 is formed with an inlet 311 through which a working liquid can flow in, and an outlet 312 through which the working liquid can flow out. The turbine 33 is disposed inside the pump housing 31. The turbine 33 is formed with a chamber 34 having a depressed shape, a second magnetic element 35 is disposed on the inner wall of the chamber 34, and the second magnetic element 35 is a magnet. A shaft pin 36 is disposed at the position in the chamber 34 corresponding to the shaft hole 121 of the second stator 12, so as to be inserted into the shaft hole 121 of the second stator 12, such that the inner wall of the chamber 34 may accommodate the second stator 12, which helps the second magnetic element 35 and the second stator 12 to induct each other. Furthermore, the turbine 33 is provided for drawing the working liquid from the inlet 311 and pumping the working liquid flow through the outlet 312.

The working liquid (which may be a liquid coolant having an excellent heat-absorbing effect) is carried within the liquid pipe 50, the liquid pipe 50 has a liquid entrance section 51 and a liquid exit section 52. The liquid pipe is in contact with heat-dissipating block 70 that is disposed on a CPU 60. One end of the liquid entrance section 51 and one end of the liquid exit section 52 are connected to the heat-dissipating block 70, and the other ends thereof are respectively connected to the inlet 311 and the outlet 312, so that the liquid entrance section 51, the liquid exit section 52 and the pump 30 form a cycle fluid loop. The liquid entrance section 51 has a first end 511 and a second end 512 on segments away from the heat-dissipating block 70, and the liquid entrance section 51 is formed with a curved portion 513 between the first end 511 and the second end 512, corresponding to a position of the radial wind outlet 212, so that the curved portion 513 is located on a wind output path of the heat-dissipating fan 20, where the curved portion 513 has several curves as to increase a heat dissipation path and a heat dissipation area. Additionally, the liquid entrance section 51 passes through the through hole 41 of the casing 40 so as to be connected to the inlet 311, and the liquid exit section 52 passes through the through hole 42 so as to be connected to the outlet 312, such that the liquid entrance section 51 and the liquid exit section 52 may be communicated with the pump housing 31 of the pump 30.

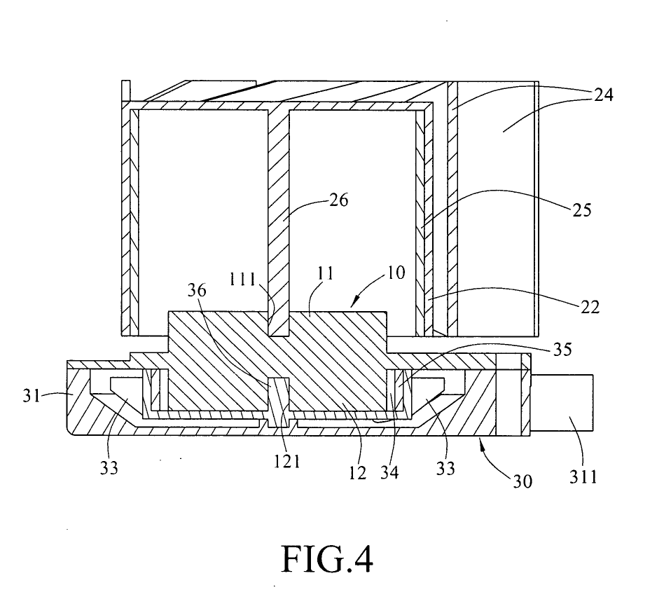

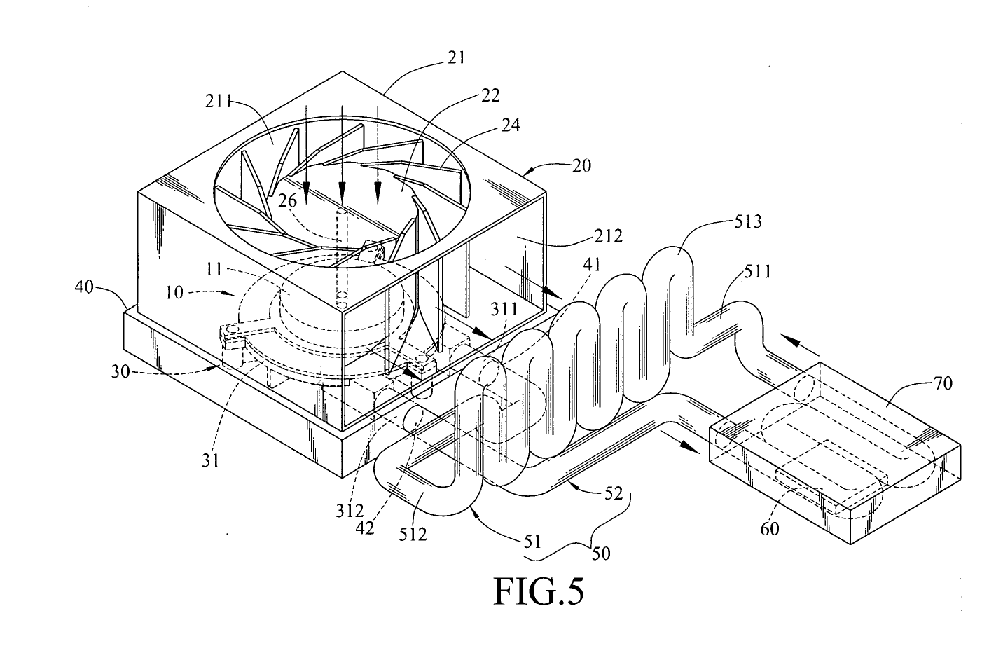

Referring again to FIGS. 2A, 2B, 3, 4, and 5, in a first embodiment of the liquid cooling type heat-dissipating device of the present invention, as being assembled, the shaft pin 36 of the chamber 34 is received in the shaft hole 121 of the second stator 12. In this way, the second stator 12 of the motor 10 is accommodated by the chamber 34 of the pump 30, such that the second stator 12 and the second magnetic element 35 within the chamber 34 may induct each other so as to drive the turbine 33 to rotate. Additionally, the shaft pin 26 of the fan hub 22 is received in the shaft hole 111 of the first stator 11, such that the first stator 11 of the motor 10 is accommodated within the fan hub 22, and thus the first stator 11 of the motor 10 and the first magnetic element 25 within the fan hub 22 may induct each other so as to drive the fan blade 24 to rotate.

After the first stator 11 and the second stator 12 of the motor 10 is powered through the power supply wire 14, the first stator 11 and the second stator 12 may generate electromagnetic induction respectively with the first magnetic element 25 and the second magnetic element 35 surrounding them, so as to drive the fan 20 and the turbine 33 to rotate.

Accordingly, when flowing through the heat-dissipating block 70, the working liquid may take away the heat from the CPU 60 and then flow into the first end 511 of the liquid entrance section 51, at this point, the working liquid in the first end 511 has a high working temperature due to carrying the heat. Also, since the power supply wire 14 is powered on, the motor 10 drives both the fan 20 and the turbine 33 to rotate at the same time.

When the working liquid is guided and driven by the pump 30, the working liquid located in the first end 511 starts to pass through the curved portion 513, at this point, the fan blades 24 may draw air flow from the axial wind inlet 211 and discharged air flow from the radial wind outlet 212, so as to forwardly blow the curved portion 513. After the working liquid in the curved portion 513 is subjected to a wind blowing, the temperature thereof begins to drop, and thus the working liquid may be cooled. When entering the second end 512 of the liquid entrance section 51, the working liquid has a lower temperature than that in the first end 511. Then, the working liquid continues to enter the pump 30 from the inlet 311, and the rotation of the blades 33 within the pump 30 may drive the working liquid in the inlet 311 to flow to the outlet 312. The working liquid then flows from the outlet 312 to the liquid exit section 52, and continues to flow toward the heat-dissipating block 70. Since the working liquid has been cooled, it may take away the heat from the CPU 60 once again. The working liquid continuously flows, which may facilitate the heat exchange, and achieve a cooling effect by a air blow and a water discharging effect for the pump, respectively.

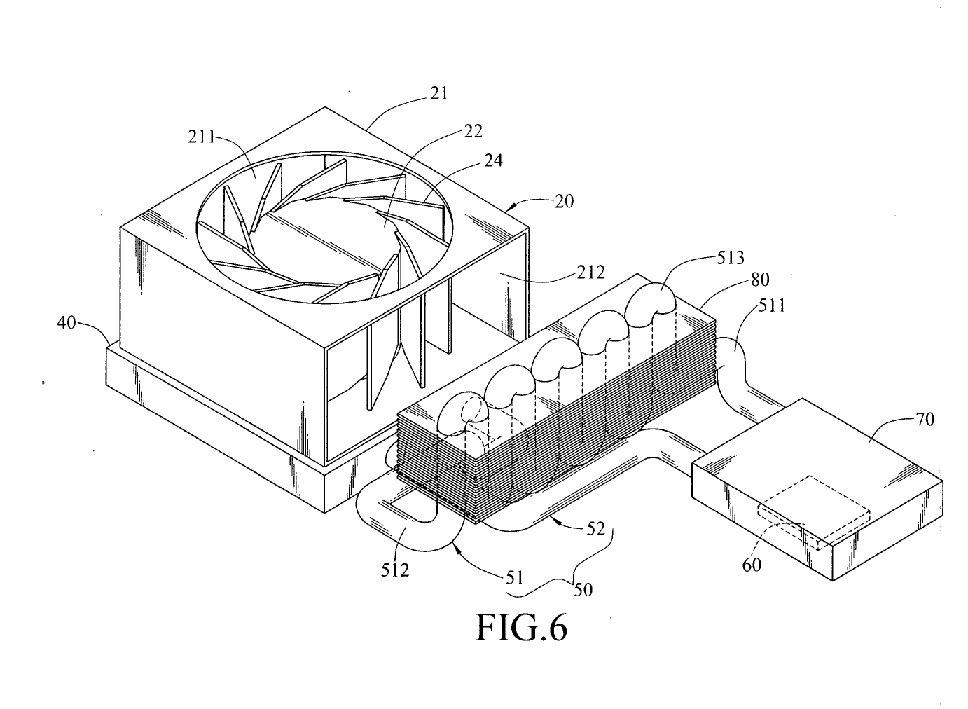

Referring to FIG. 6, a schematic view of a forward wind blow of a second embodiment to the liquid cooling type heat-dissipating device according to the present invention is shown. Since the curved portion 513 in the liquid entrance section 51 has a large heat dissipation area, and a position corresponding to the radial wind outlet 212 is blown by the heat-dissipating fan 20, the curved portion 513 is used as a temperature dropping section for the working liquid, therefore, when the curved portion 513 of the liquid entrance section 51 is further connected to a heat exchanger 80, the working liquid within the liquid entrance section 51 may be cooled more quickly and thus more heat may be dissipated.

Moreover, the above-mentioned motor 10 rotates the fan blade 24 and the blades 33 coaxially and at the same speed. However, the motor 10 may also rotate the fan blade 24 and the blades 33 uncoaxially and at different revolving speeds, and thus a third embodiment is disclosed in the present invention.

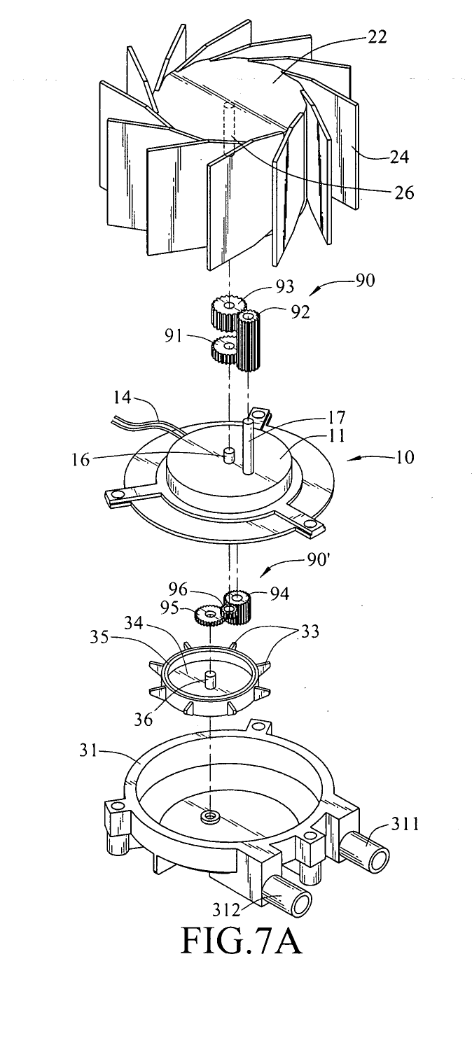

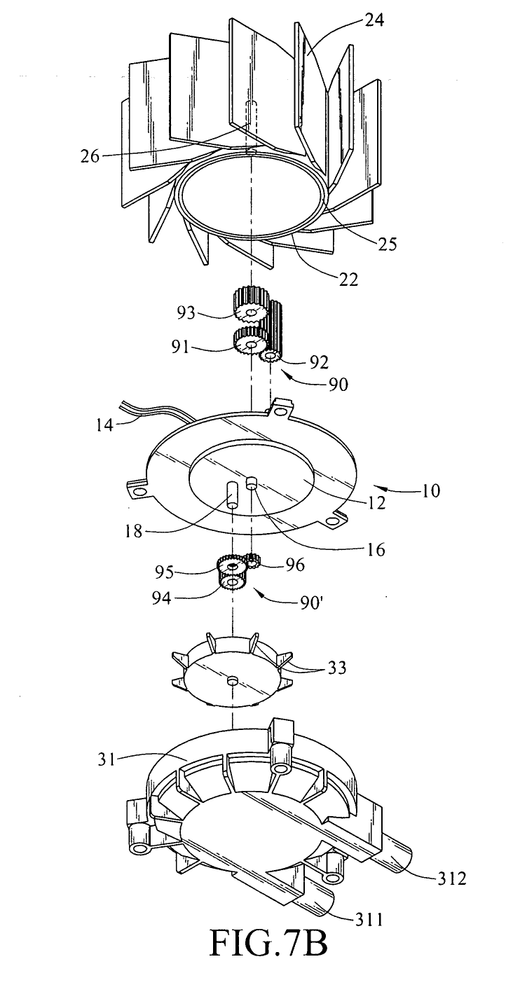

Referring to FIGS. 7A and 7B, in order to make the motor 10, the fan hub 22 and the turbine 33 be located in different axis positions, a central shaft 16 having two ends projected from the end surfaces of the first stator 11 and the second stator 12 is disposed in the motor 10, and eccentric shafts 17, 18 are respectively disposed on the end surfaces of the first stator 11 and the second stator 12, adjacent to the central shaft 16. Additionally, a first gear set 90 and a second gear set 90′ with different reduction gear ratios are respectively disposed between the motor 10 and the fan hub 22 and between the motor 10 and the turbine 33. In this way, when the motor respectively drives the fan hub 22 and the turbine 33, the output at two sides of the motor 10 are different, so that the fan hub 22 and the turbine 33 have different revolving speeds. The first gear set 90 includes a first gear 91, a second gear 92 and a third gear 93, and the second gear set 90′ includes a fourth gear 94, a fifth gear 95 and a sixth gear 96, but the constitution of the first gear set 90 and the second gear set 90′ is not limited to this. Here, the first gear set 90 and the second gear set 90′ respectively including three gears with different diameters are taken as an example. The first gear 91 is pivoted at one end of the central shaft 16 of the motor 10 on the first stator 11, the second gear 92 is pivoted at the eccentric shaft 17, the third gear 93 is pivoted at the shaft lever 26 of the fan hub 22, the fourth gear 94 is pivoted at the eccentric shaft 18, and the fifth gear 95 is pivoted at the shaft lever 36 of the chamber 34. In addition, the sixth gear 96 is pivoted at one end of the central shaft 16 of the motor 10 on the second stator 12. Furthermore, the second gear 92 is geared with the first gear 91 and the third gear 93, and the fourth gear 94 is geared with the fifth gear 95 and the sixth gear 96. In this way, when the motor drives the fan hub 22 and the turbine 33 under the electromagnetic induction, the fan hub 22 and the turbine 33 have different revolving speeds in different axis positions, so as to meet users' requirements.

The liquid cooling type heat-dissipating device disclosed by the present invention integrates a heat-dissipating fan and a pump together through a motor, which may reduce an occupied volume and save an inner space. Also, a wind inlet and a wind outlet of the heat-dissipating fan are formed along an axial direction and a radial direction of a fan blade, which will not cause barrier on the introduction and exportation paths of an air flow, thereby reducing a wind resistance to achieve a large air volume. Additionally, there is a working liquid having an excellent heat dissipation effect in a liquid pipe to dissipate heat, and a partial segment of a liquid entrance section is formed with a curved portion which prolongs a heat dissipation path of the working liquid and also increases a heat dissipation area thereof, therefore, the temperature dropping time may be increased. Because the curved portion is located on a wind output path of the heat-dissipating fan, such as the radial wind outlet, the wind resistance may be reduced and more wind power may be used to cool an outer part of the liquid pipe when the curved portion is forwardly blown by the heat-dissipating fan from the radial wind outlet. In this way, the liquid pipe may achieve a better heat dissipation efficiency through inner and outer heat dissipation processes.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A liquid cooling type heat-dissipating device, for dissipating heat from a heat source, and comprising a heat-dissipating fan, a pump, a liquid pipe, a motor and a heat-dissipating block, wherein the motor drives the heat-dissipating fan and the pump, two ends of the liquid pipe are connected to the pump so as to form a fluid loop, the liquid pipe is in contact with the heat-dissipating block, and the heat-dissipating block is disposed on the heat source, wherein the liquid pipe is continuously curved on a segment away from the heat-dissipating block to form a curved portion located on a wind output path of the heat-dissipating fan.

2. The liquid cooling type heat-dissipating device as claimed in claim 1, wherein the liquid pipe is connected to a heat exchanger.

3. The liquid cooling type heat-dissipating device as claimed in claim 2, wherein the heat exchanger is located at the curved portion of the liquid pipe.

4. The liquid cooling type heat-dissipating device as claimed in claim 1, wherein the liquid pipe has a liquid entrance section and a liquid exit section, the liquid entrance section has a first end and a second end, and the curved portion is located between the first end and the second end.

5. The liquid cooling type heat-dissipating device as claimed in claim 4, wherein a working temperature of the second end is lower than that of the first end.

6. The liquid cooling type heat-dissipating device as claimed in claim 1, wherein a first gear set and a second gear set with different speed reducing ratios are respectively disposed between the motor and the heat-dissipating fan and between the motor and the pump, and the motor drives the heat-dissipating fan and the pump at different revolving speeds.

7. The liquid cooling type heat-dissipating device as claimed in claim 6, wherein a central shaft is disposed in the motor, the central shaft extends out of two opposite side surfaces of the motor, and an eccentric shaft is respectively disposed on the two opposite side surfaces of the motor adjacent to the central shaft, the first gear set is pivoted on the central shaft and one eccentric shaft, and the second gear set is pivoted on the central shaft and the other eccentric shaft, such that the motor drives the heat-dissipating fan and the pump at different revolving speeds.
